(19) United States
(12) Patent Application Publication
(10) Pub. No.: US 2004/0174674 A1
(43) Pub. Date: Sep. 9, 2004

(54) Method for monitoring a computer system

(76) Inventors: Thomas E. Stewart, Saratoga, CA (US); Tam Q. Vu, San Jose, CA (US)

Correspondence Address: HOYT A. FLEMING III, P.O. BOX 140678, BOISE, ID, 83714, US

(21) Appl. No.: 10/379,482

(22) Filed: Mar. 4, 2003

(51) Int. Cl. H05K 7/20

(52) U.S. Cl. 361/687

(57) ABSTRACT

A method of monitoring a computer system. The method includes determining the temperature at a first location within the computer system and determining the temperature at a second location within the computer system. The method also includes determining the difference between the temperature at the first location and the temperature at the second location. If the difference between the temperature at the first location and the temperature at the second location is greater than a predetermined temperature, then generating a message that interprets the temperature condition. The message may refer to a written document, such as a user manual, that provides a detailed interpretation of the temperatures.

### FIELD OF THE INVENTION

The present invention generally relates to methods for monitoring a computer system. More specifically, the present invention relates to monitoring one or more temperatures within a computer system, interpreting the temperatures, and generating descriptive messages when necessary.

### BACKGROUND

Many modern industrial computer systems are designed so that the functionality of the computer system can be rapidly modified. Instead of utilizing a “motherboard” as found in most desktop computer systems, many modern industrial computers utilize a backplane that includes a number of connectors for receiving circuit board assemblies. These circuit board assemblies include numerous components that increase the functionality of the computer system. As a result, high-performance computer systems can be easily assembled. One unfortunate side effect of building such high-performance computer systems is that the systems dissipate large amounts of heat, particularly in the confined spaces of the rack-mounted enclosures. In order to keep the components of the circuit board assemblies from over-heating, such computer systems utilize one or more fans to blow air over the components. Unfortunately, fans may fail or have their capacity reduced. For example, a fan bearing may seize, a fan motor may “burn out,” or a fan air filter may clog. In addition, a physical blockage may occur or an air inlet or air exhaust may be blocked.

Some high-performance computer systems include monitoring systems that measure various temperatures within the computer system. Temperature sensors that can be utilized to measure temperatures within a computer system include resistance temperature devices (“RTD”), themistors, and thermocouples. These sensors can provide processors, either directly, or via converter circuits, with temperature readings at various locations within the computer system. As is known in the art, the processors can be programmed to provide the measured temperatures to a user. However, users have difficulty interpreting such temperature data. For example, a user may not know what action to take to reduce a particular temperature.

Thus, a need exists for a monitoring system capable of measuring and interpreting temperatures within a computer system and then providing a user with a message resulting from the interpretation.

### SUMMARY OF THE INVENTION

One embodiment of the invention is a method of monitoring a computer system. The method includes determining the temperature at a first location within the computer system and determining the temperature at a second location within the computer system. The method also includes determining the difference between the temperature at the first location and the temperature at the second location. If the temperature difference is greater than a predetermined temperature, the method includes generating a message that interprets the temperature condition.

Another embodiment of the invention is a second method of monitoring a computer system. The method includes determining the temperature at a location within the computer system and if the temperature at the location is greater than a predetermined temperature, then generating a message. The message requests a user to ensure room air temperature does not exceed a certain temperature or to ensure no physical blockage of airflow upstream of the board exists.

Other embodiments of the invention include methods that generate messages that indicate that an inlet or an exhaust temperature is greater than a predetermined temperature.

Still other embodiments of the invention include computer systems that are programmed to perform the above methods. Such computer systems may include a first temperature sensor for measuring a first temperature and a second temperature sensor for measuring a second temperature. The computer systems may also include a processor that is coupled to the first temperature sensor and the second temperature sensor. The computer systems may include a program storage device that is coupled to the processor. The program storage device may contain instructions that when executed by the processor perform portions of the above methods.

### BRIEF DESCRIPTION OF THE FIGURES

FIG. 1 presents a flow chart of a method of monitoring a computer system.

FIG. 2 presents a block diagram of a computer system.

FIG. 3 presents a flow chart of another method of monitoring a computer system.

FIG. 4 presents a flow chart of another method of monitoring a computer system.

FIG. 5 presents a flow chart of another method of monitoring a computer system.

FIG. 6 presents a flow chart of another method of monitoring a computer system.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not intended to be limited to the embodiments shown, but is to be accorded the widest scope consistent with the principles and features disclosed herein.

Generally, several embodiments of the invention relate to monitoring one or more temperatures within a computer system, interpreting the temperatures, and then generating a message resulting from the interpretation so that a user will be better equipped to solve a temperature condition that is outside of predetermined tolerances.

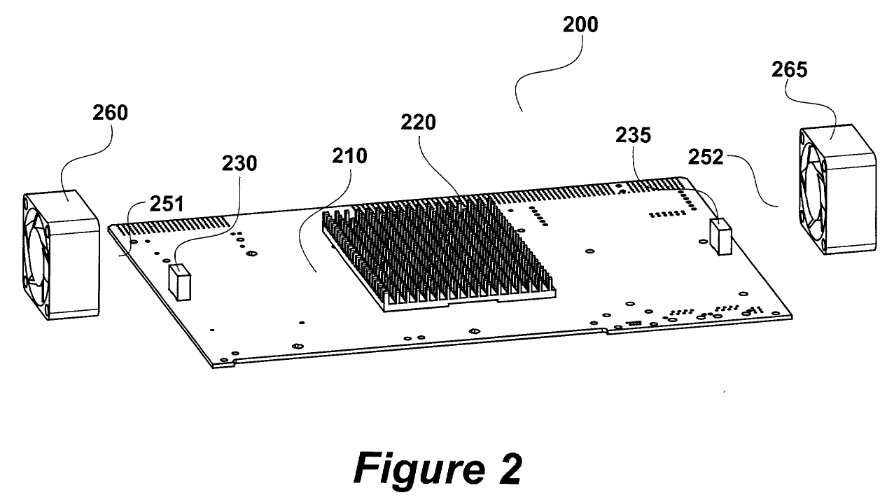

One embodiment of the invention, which may be utilized by the computer system 200, shown in FIG. 2, is a method of monitoring a computer system.

FIG. 2 presents a simplified block diagram of a computer system 200 that includes a circuit board 210. The circuit board 210 includes a processor 220, a first temperature sensor 230, and a second temperature sensor 235. Airflow moves across the circuit board 210 from the inlet 251, over the processor 220, to the exhaust 252. When the airflow moves across the processor 220, the air is heated. Thus, the temperature at the exhaust 252 will be greater than the temperature at the inlet 251.

Those skilled in the art will appreciate that the block diagram of FIG. 2 is simplified to illustrate only those functional elements of interest in describing the present invention. Other functional elements are not shown. For example, the circuit board 210 may be one of many circuit boards that plug into a backplane to create a computer system. Alternatively, circuit board 210 may be a motherboard that contains a large variety of electrical components.

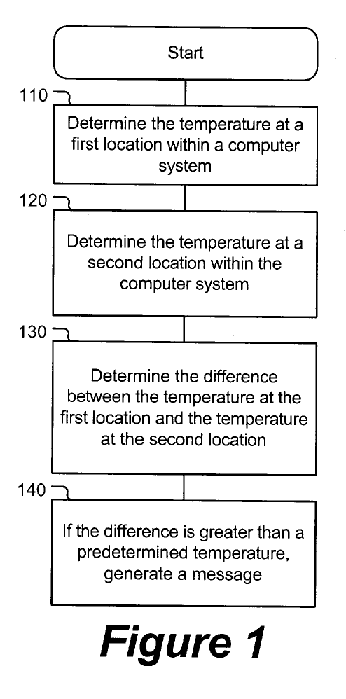

5.1 Determining the Temperature at a First Location Another embodiment of the invention is a method of monitoring a computer system. This method is shown in FIG. 1. Referring to block 110 of FIG. 1, one step in the method is determining the temperature at a first location within the computer system. As is known in the art, the temperature of a location within a computer system can be determined in many ways. For example, temperature sensor 230 could determine the temperature of the inlet 251.

5.2 Determining the Temperature at a Second Location

Referring to block 120 of FIG. 1, the temperature at a second location within the computer system is determined. For example, the temperature sensor 235 could be utilized to measure the temperature of the exhaust 252.

5.3 Determining the Difference in the Temperatures

As shown in block 130 of FIG. 1, the temperature difference between the inlet 251 and the exhaust 252 is determined. This determination could be performed by a processor 220 coupled to the temperature sensors 230 and 235. The processor could be a general-purpose processor, a special-purpose processor, a digital signal processor, or a controller.

5.4 Generating a Message

As shown in block 140 of FIG. 1, once the temperature difference is determined, the temperature difference is compared to a predetermined temperature difference. If the temperature difference is greater than the predetermined temperature difference, then a message that interprets the temperature difference is generated. For example, the generated message could indicate that a particular processor, electrical component, or circuit board may be overheating, that a system fan may have failed, or that an air filter may not be allowing sufficient airflow. After reviewing the generated message, then the user could take the appropriate action to reduce the temperature differences.

5.5 Another Method of Monitoring a Computer System

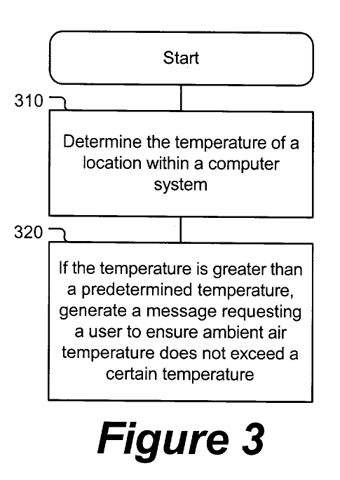

Another embodiment of the invention, which is shown in FIG. 3, is another method of monitoring a computer system. In this embodiment, as shown in block 310, the first step is determining a temperature at a location within the computer system. For example, the inlet temperature of air entering into a computer system or the inlet temperature of air intended to cool a particular circuit board assembly in a computer system could be determined utilizing the various methods previously discussed.

Next, as shown in block 320 of FIG. 3, if the temperature at the location is greater than a predetermined temperature, then a message is generated that interprets the temperature. For example, a message requesting a user to ensure that the ambient air temperature does not exceed a certain temperature may be generated. By providing a user with such a message, the user will be better equipped to solve the exceeded temperature problem.

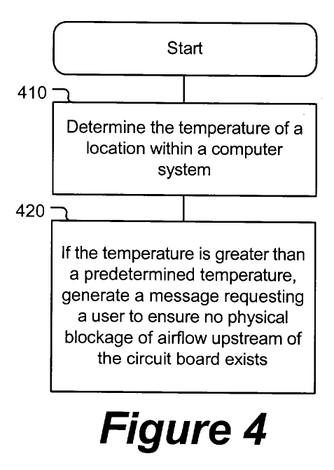

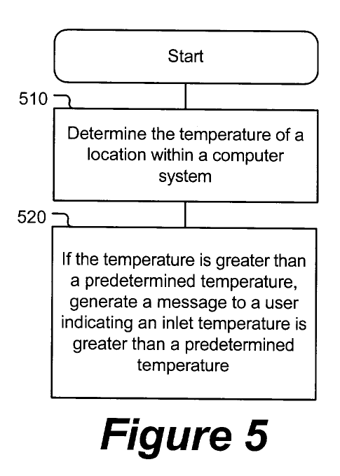

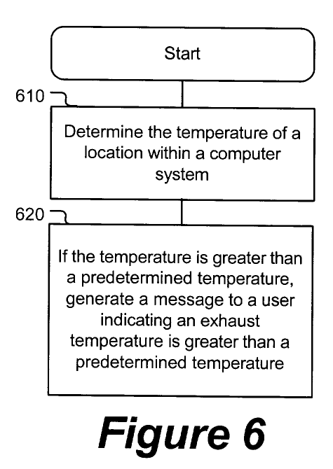

In still other embodiments of the invention, other interpretive messages are generated. For example, as shown in FIG. 4, a message may be generated that requests a user to ensure that no upstream physical blockage of airflow exists. As shown in FIG. 5, a message may be generated that an upstream component, assembly, or even a fire has caused an inlet temperature to be greater than a predetermined temperature. Similarly, as shown in FIG. 6, a message could be generated indicating that an overheating component, overheating assembly or even a fire has caused an exhaust temperature to be greater than a predetermined temperature.

5.6 Other Embodiments of the Invention

In some embodiments of the invention, the generated message may refer the user to a document such as a user manual. For example, the message may indicate the inlet temperature and the exhaust temperature. The message could then refer the user to a specific page in a user manual that explains how to interpret these temperatures. The user manual could explain to the user that the user should monitor the inlet temperature to ensure that room air ambient temperature is not exceeding a predetermined temperature or that there is no physical blockage on the board. In addition, the user manual could also indicate that the user should monitor inlet temperature to insure that there is no significant heat source, such as an overheating component, overheating assembly, or even a fire, upstream of the inlet temperature sensor. The user manual could also indicate that the user should monitor the difference between the inlet and exhaust temperatures to determine if a component on the circuit board is overheating, one or more system fans have failed, and/or filters are clogged and choking inlet air thereby not adequately allowing air to cool the circuit board.

5.7 Still Other Embodiments of the Invention

In still other embodiments of the invention, if the difference between a first temperature, such as the temperature at the inlet 251 and a second temperature, such as the temperature at the exhaust 252, is below a predetermined temperature difference, then a message may be generated. This message could indicate that a computer system, such as a “blade” computer, may not be functioning properly because the computer system is not drawing sufficient power. Thus, the computer system may need to be repaired.

In some embodiments of the invention, a computer system may store temperatures over a period of time, such as hours, days, or even months. If the computer system determines that the rate of change of the temperature exceeds a predetermined temperature rate, then a message may be generated. This message could indicate that an air filter may be clogging and that the filter should be cleaned. Similarly, the computer system may store temperature differences over a period of time, and may generate messages based upon the rate of change of such temperature differences.

In some embodiments of the invention, a computer system may monitor its own temperatures and temperature differences. Such a computer system could generate messages based upon such temperatures and temperature differences. However, in other embodiments of the invention, one computer system may monitor a number of other computer systems. In such embodiments of the invention, the monitoring computer system, as opposed to the monitored computer system, would generate messages. The monitoring computer system may be in a separate computer rack, a separate computer room, or even in a separate building from the monitored computer systems.

In such embodiments of the invention, the lack of a timely reporting of temperature values could indicate that the monitored computer system has lost power or has failed. Thus, the monitoring computer system may generate a message indicating the absence of timely temperature data. Similarly, the lack of timely reporting of temperature values from a number of computer systems may indicate that a specific computer rack has lost power, a computer room has lost power, a floor has lost power, or even an entire building has lost power. Thus, messages that indicate the computer rack, the computer room, the building floor, and/or the building that has lost power could be generated.

Similarly, by analyzing temperatures and/or temperature differences of a number of monitored computer systems, the monitoring computer system could generate messages that indicate a number of other problems or potential problems, as discussed above, in specific computer racks, computer rooms, building floors, and/or buildings. In buildings with a large number of computer systems, messages that indicate the precise location and scope of a potential or actual problem could be valuable and could result in increased system availability, reduced capacity loss, and reduced repair times. Such messages could be utilized to indicate the need to reroute critical data away from troubled locations until the problems were corrected.

5.8 A Computer System for Performing One or More of the Above Methods

Another embodiment of the invention is a computer system that is programmed to perform any of the methods described above. The computer system could include one or more temperature sensors for measuring one or more temperatures. The computer system could also include a processor that is coupled to the temperature sensors and is also coupled to a program storage device. The program storage device could contain instructions that when executed, perform one or more of the previously discussed monitoring methods.

Still other embodiments of the invention include a program storage device containing instructions that when executed by a computer system perform portions of the above methods.

5.9 Conclusion

The foregoing descriptions of embodiments of the present invention have been presented for purposes of illustration and description only. They are not intended to be exhaustive or to limit the present invention to the forms disclosed. Accordingly, many modifications and variations will be apparent to practitioners skilled in the art. For example, many of the methods discussed above for monitoring a computer system may be combined. As a result, a complex airflow can be monitored. For example, the inlet airflow temperature to a computer system could be monitored. If this inlet airflow temperature is greater than a predetermined temperature, then a message that interprets the temperature could be generated. Next, the inlet and exhaust airflow temperatures of a particular circuit board could be measured. If the difference between these temperatures exceeds a predetermined difference, then an interpretive message could be generated that informs the user that the circuit board is overheating. Similarly, “downstream” circuit board inlet and exhaust temperatures could be measured. If the difference between these “downstream” temperatures exceeded a predetermined temperature difference, then an interpretive message that indicates that the “downstream” circuit board is overheating could be generated. By utilizing a number of temperature sensors and processing logic, a user can be provided with detailed messages that provides the user specific actions to take to remedy exceeded temperature conditions.

The above disclosure is not intended to limit the present invention. The scope of the present invention is defined by the appended claims.

It is claimed:

1. A method of monitoring a computer system, the method comprising:
a) determining the temperature at a first location within the computer system;
b) determining the temperature at a second location within the computer system;
c) determining the difference between the temperature at the first location and the temperature at the second location; and
d) if the difference between the temperature at the first location and the temperature at the second location is greater than a predetermined temperature, then generating a message.

2. The method of claim 1, wherein determining the temperature at the first location includes determining an inlet temperature to a circuit board assembly.

3. The method of claim 1, wherein determining the temperature at the first location includes determining an inlet temperature to a circuit board assembly that includes a processor.

4. The method of claim 1, wherein determining the temperature at the second location includes determining an exhaust air temperature of a circuit board assembly.

5. The method of claim 1, wherein generating the message includes generating a message that indicates that a circuit board assembly may be overheating.

6. The method of claim 1, wherein generating the message includes generating a message that indicates that a system fan may have failed.

7. The method of claim 1, wherein generating the message includes generating a message that indicates that a filter may not be allowing sufficient airflow.

8. The method of claim 1, wherein generating the message includes generating a message that refers to a written document.

9. A method of monitoring a computer system, the method comprising:
a) determining the temperature at a location within the computer system; and
b) if the temperature at the location is greater than a predetermined temperature, then generating a message requesting a user to ensure room air temperature does not exceed a certain temperature.

10. A method of monitoring a computer system, the method comprising:
a) determining the temperature at a location within the computer system; and
b) if the temperature at the location is greater than a predetermined temperature, then generating a message requesting a user to ensure no physical blockage of airflow upstream of the board exists.

11. A method of monitoring a computer system, the method comprising:
a) determining the temperature at a location within the computer system; and
b) if the temperature at the location is greater than a predetermined temperature, then generating a message to a user indicating an inlet temperature is greater than a predetermined temperature.

12. A method of monitoring a computer system, the method comprising:
a) determining the temperature at a location within the computer system; and
b) if the temperature at the location is greater than a predetermined temperature, then generating a message to a user indicating an exhaust temperature is greater than a predetermined temperature.

13. A system for monitoring a computer system, the system comprising:
a) a first temperature sensor for measuring a first temperature;
b) a second temperature sensor for measuring a second temperature;
c) a processor that is coupled to the first temperature sensor and the second temperature sensor;
d) a program storage device that is coupled to the processor, the program storage device containing instructions that when executed by the processor performs a method that includes:
1) determining the temperature at a first location within the computer system;
2) determining the temperature at a second location within the computer system;
3) determining the difference between the temperature at the first location and the temperature at the second location; and
4) if the difference between the temperature at the first location and the temperature at the second location is greater than a predetermined temperature, then generating a message.

14. The system of claim 13, wherein the first temperature sensor measures an inlet temperature to a circuit board assembly.

15. The system of claim 13, wherein the second temperature sensor measures an exhaust air temperature of a circuit board assembly.

16. The system of claim 13, wherein generating the message includes generating a message that indicates that a circuit board assembly may be overheating.

17. The system of claim 13, wherein generating the message includes generating a message that indicates that a system fan may have failed.

18. The system of claim 13, wherein generating the message includes generating a message that indicates that a filter may not be allowing sufficient airflow.

19. The method of claim 13, wherein generating the message includes generating a message that refers to a written document.

20. A system for monitoring a computer system, the system comprising:
a) a temperature sensor for measuring a temperature;
b) a processor that is coupled to the temperature sensor;
c) a program storage device that is coupled to the processor, the program storage device containing instructions that when executed by the processor performs a method that includes:
d) determining the temperature at a location within the computer system; and
1) if the temperature at the location is greater than a predetermined temperature, then generating a message requesting a user to ensure room air temperature does not exceed a certain temperature.

21. A system for monitoring a computer system, the system comprising:
a) a temperature sensor for measuring a temperature;
b) a processor that is coupled to the temperature sensor;
c) a program storage device that is coupled to the processor, the program storage device containing instructions that when executed by the processor performs a method that includes:
d) determining the temperature at a location within the computer system; and
1) if the temperature at the location is greater than a predetermined temperature, then generating a message indicating that an inlet temperature is greater than a predetermined temperature.

22. A system for monitoring a computer system, the system comprising:
a) a temperature sensor for measuring a temperature;
b) a processor that is coupled to the temperature sensor;
c) a program storage device that is coupled to the processor, the program storage device containing instructions that when executed by the processor performs a method that includes:
1) determining the temperature at a location within the computer system; and
2) if the temperature at the first location is greater than a predetermined temperature, then generating a message requesting a user to ensure no physical blockage of airflow upstream of the board exists.

23. A method of monitoring a computer system, the method comprising:
a) determining the temperature at a first location within the computer system;
b) determining the temperature at a second location within the computer system;
c) determining the difference between the temperature at the first location and the temperature at the second location; and
d) if the difference between the temperature at the first location and the temperature at the second location is less than a predetermined temperature, then generating a message.
